(19) United States
(12) Patent Application Publication
(10) Pub. No.: US 2006/0079021 A1
(43) Pub. Date: Apr. 13, 2006

(54) Method for flip chip package and structure thereof

(75) Inventor: Chih-An Yang, Shindian City (TW)

Correspondence Address: BIRCH STEWART KOLASCH & BIRCH, PO BOX 747, FALLS CHURCH, VA, 22040-0747, US

(73) Assignee: VIA TECHNOLOGIES, INC.

(21) Appl. No.: 11/220,708

(22) Filed: Sep. 8, 2005

(30) Foreign Application Priority Data
Sep. 24, 2004 (TW) 093129136

(51) Int. Cl. H01L 21/48

(52) U.S. Cl. 438/108

(57) ABSTRACT

A method for flip chip package and structure thereof is disclosed. The present invention is using an eutectic bonding process to connect a chip and a heatsink for enhancing thermal dissipation capability from the chip to the heatsink and ensuring the chip working well. The method for flip chip package at least includes the steps of providing a heatsink having a surface plated with a gold film and a bare surface, providing a chip having a join surface and an active surface with a plurality of contacts, eutectic bonding the join surface of the chip to the gold film of the heatsink by gold-silicon diffusion for connecting the chip to the heatsink, connecting the active surface of the chip to a substrate by flip chip technology; and dispensing an underfill into the gap between the chip and the substrate.

### BACKGROUND OF THE INVENTION

1. Field of Invention

The present invention relates to a flip chip package, and in particular, to a method for flip chip package and structure thereof by connecting a chip with a heatsink by using an eutectic bonding process.

2. Related Art

Flip chip package has been widespread applied to semiconductor package. Comparing to prior wire bonding ball grid array (WBBGA), flip chip package reverses a chip and mechanically and electrically connects an active surface (the surface with electronic circuit and devices) of the chip to a substrate by plural solder bumps. An insulating underfill is then dispensed into the gap between the solder bumps and between the chip and the substrate for solid connection. Because no wire is needed for electrical connection, flip chip package can reduce the packaging size and be more compact.

However, accompanying to the progress of functionality of integrated circuit, the chip dissipates much more heat during operation. In order to prevent the reduction of reliability of the chip caused by dissipated heat, heat dissipation has become a major issue, especially to the products of high power consumption such as central processing unit (CPU) and graphics processing unit (GPU). Heat dissipation capability is now an essential index to the electronic products.

One key factor of heat dissipation capability of flip chip packaging is dominated by thermal resistivity of its thermal interface material (TIM) disposed between the heatsink and the chip. In prior art, the most popular TIM on CPU is thermal grease or phase change material, such as epoxy based material or tin-lead solder, the resistivity is too high to get a good result.

FIGS. 1 to 3 show a conventional process for flip chip package. Firstly, a chip 20a is reversely disposed on a substrate 30a and electrically connected to the substrate 30a by plural solder bumps. A plurality of terminals 31a disposed at bottom side of the substrate 30a are electrically connected with the chip 20a.

An insulating underfill 32a is then dispensed into the gap between the solder bumps and between the chip 20a and the substrate 30a for solid connection.

Finally, a heatsink 10a is attached on the chip 20a by a TIM 12a. In order to prevent the damage from moisture, a sealing material (not shown) could be further disposed between the heatsink 10a and the substrate 30a.

That is, prior arts still have lots of disadvantages as follows:

1. The thermal conductivity of epoxy based TIM is too low to have a good thermal dissipation capability. The TIM will block the heat transfer from the chip to the heatsink.

2. The thermal grease as the TIM on the back of the chip will be pump-out during the operation by its temperature cycling. The heatsink will be lifted after a period of operating.

3. For the solder bonding process between flip chip and heatsink, the thermal conductivity is higher than the epoxy based TIM but still a major thermal resistance. By the way, the solder with lead is still an environmental consideration.

4. For solder joint adhesion, the coefficient of thermal expansion (CTE) mismatch between silicon and solder is higher to have a stress concentration point in the interface.

It is therefore an important subject of the present invention to provide a method for flip chip package and structure thereof to solve above-mentioned problems and achieve an excellent thermal conductivity.

### SUMMARY OF THE INVENTION

In view of the foregoing, one aspect of the present invention is to provide a method for flip chip package and structure thereof for enhancing thermal dissipation capability from the chip to the heatsink.

Another aspect of the present invention is to provide a method for flip chip package and structure thereof for better connection between the chip and the heatsink to prevent from stress at the interface.

To achieve the above, a method for flip chip package according to the present invention at least includes the steps of providing a heatsink having a surface plated with a gold film and a bare surface, providing a chip having a join surface and an active surface with a plurality of contacts, eutectic bonding the join surface of the chip to the gold film of the heatsink by gold-silicon diffusion for connecting the chip to the heatsink, connecting the active surface of the chip to a substrate by flip chip technology; and dispensing an underfill into the gap between the chip and the substrate.

To achieve the above, a structure of flip chip package according to the present invention at least includes a heatsink, a chip, a gold-silicon intermetallic layer, a substrate and an underfill. The heatsink has a surface plated with a gold film and a bare surface. The chip has a join surface and an active surface with a plurality of contacts. The gold-silicon intermetallic layer is disposed between the gold film of the heatsink and the join surface of the chip. The active surface of the chip is connected to the substrate by flip chip technology. The underfill is dispensed into the gap between the chip and the substrate.

As mentioned above, by using the eutectic bonding process to form a gold-silicon intermetallic layer with high thermal conductivity between a chip and a heatsink, the present invention enhances thermal dissipation capability from the chip to the heatsink and ensuring the chip working well.

### BRIEF DESCRIPTION OF THE DRAWINGS

The present invention will become more fully understood from the detailed description given herein below illustration only, and thus is not limitative of the present invention, and wherein:

FIG. 1 is a schematic view showing a chip connected to a substrate of a conventional flip chip package;

FIG. 2 is a schematic view showing an underfill dispensed into the gap between the chip and the substrate of the conventional flip chip package;

FIG. 3 is a schematic view showing a heatsink connected to the chip of the conventional flip chip package;

FIG. 4 is a schematic view showing a heatsink with a gold film thereon according to the present invention;

FIG. 5 is a schematic view showing an eutectic bonding between the heatsink and a chip according to the present invention;

FIG. 6 is a schematic view showing the heatsink connected to the chip according to the present invention; and

FIG. 7 is a schematic view showing the chip connected to a substrate and an underfill dispensed into the gap between the chip and the substrate according to the present invention.

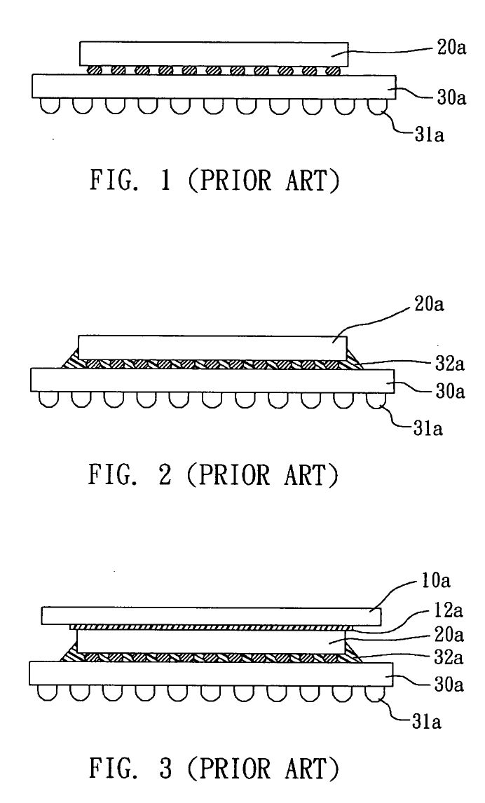

### DETAILED DESCRIPTION OF THE INVENTION

The present invention will be apparent from the following detailed description, which proceeds with reference to the accompanying drawings, wherein the same references relate to the same elements.

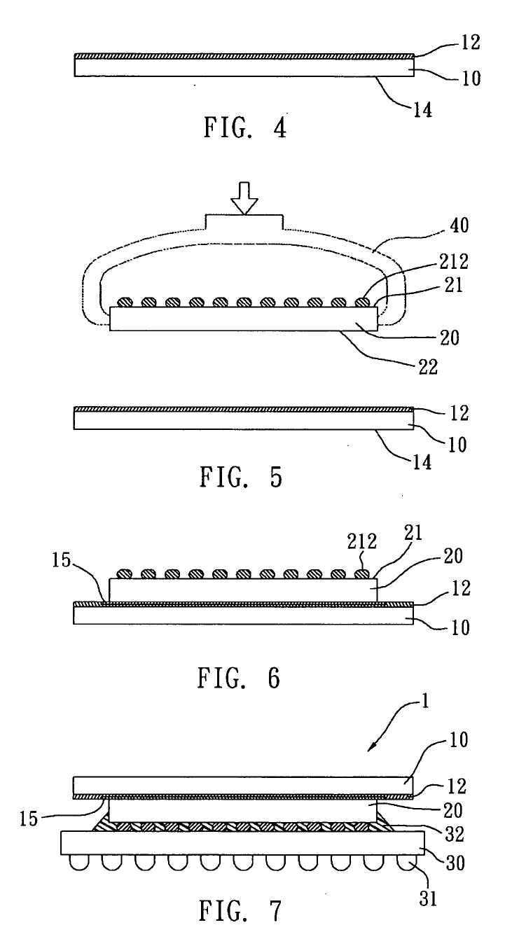

FIGS. 4 to 7 show a method for a flip chip package according to the present invention. As shown in FIG. 4, a heatsink 10 having a surface plated with a gold film 12 and a bare surface 14 is provided.

As shown in FIG. 5, a chip 20 having a join surface 22 and an active surface 21 with a plurality of contacts 212 is provided. Then, a clamping apparatus 40 to clamp the chip 20 and to dispose the join surface 22 of the chip 20 onto the gold film 12 of the heatsink 10.

As shown in FIG. 6, the join surface 22 of the chip 20 is connected to the gold film 12 of the heatsink 10 by an eutectic bonding process. Due to the chip 20 is made of silicon, eutectic reaction between gold and silicon at about 363° C. will form a gold-silicon intermetallic layer by gold-silicon diffusion. Preferably, the heatsink 10 is heated up to about 425° C. to form the connection in a nitrogenous ambiance to prevent silicon from oxidization. The join surface 22 and the gold film 12 may be scrubbed to remove silicon oxidization layer at the surface for increasing wetting property of the reactive surface.

The temperature of the heatsink 10 will raise by scrubbing and the heatsink 10 is heated to over 350° C. and under 450° C. Oscillating energy caused by scrubbing is transformed to be melting energy and which enhances the diffusion between gold and silicon. The join surface 22 of the chip 20 and the gold film 12 of the heatsink 10 are scrubbed over 15 seconds and under 25 seconds, then a gold-silicon intermetallic layer 15 is formed. The scrubbing time may be longer according to practical requirement. The composition of the gold-silicon intermetallic layer 15 is not uniform, the position near the gold film 12 has a higher concentration of gold atoms and that near the chip 20 has a higher concentration of silicon atoms.

The present invention connects the chip 20 to the heatsink 10 by the gold-silicon intermetallic layer 15 for improving thermal conductivity. The thermal conductivity of the gold-silicon intermetallic layer 15 is higher than epoxy based TIM and tin-lead solder, for example, the thermal conductivity of Au/3Si is about 216 W/m° C., TIM is about 0.88 W/m° C., and Sn63/Pb37 is about 51 W/m° C. That is, the thermal conductivity of the Au/3Si intermetallic material is 245 times higher than TIM and 4 times higher than tin-lead alloy, and also the thermal conductivity of Au/3Si intermetallic material is similar the same of Au (297 W/m° C.) and better than silicon (149 W/m° C.) itself. Comparing to prior arts, the gold-silicon intermetallic layer 15 according to the present invention needs no curing and reflow soldering process, and simplifies process flow and saving process time.

The heatsink 10 according to the present invention may be fixed by a tooling and the tooling heats the bare surface 14 of the heatsink 10.

The chip 20 may be heated by the clamping apparatus 40. Preferably, the chip 20 is heated to between 150° C. and 200° C.

As shown in FIG. 7, the active surface 21 of the chip 20 is connected to a substrate 30 by flip chip package technology. Finally, an underfill 32 is dispensed into the gap between the chip 20 and the substrate 30.

A flip chip package structure 1 in FIG. 7 according to the present invention formed by the disclosed method for flip chip package includes a heatsink 10, a chip 20, a gold-silicon intermetallic layer 15, a substrate 30 and an underfill 32. The heatsink 10 has a surface plated with a gold film 12 and a bare surface 14. The chip 20 has a join surface 22 and an active surface 21 with plural contacts 212. The gold-silicon intermetallic layer 15 is disposed between the gold film 12 of the heatsink 10 and the join surface 22 of the chip 20. The active surface 21 of the chip 20 is connected to the substrate 30 by flip chip package technology. The underfill 32 is dispensed into the gap between the chip 20 and the substrate 30. The flip chip package structure 1 may further includes an encapsulation material surrounding the heatsink and between the heatsink 10 and the substrate 30.

In summary, the present invention achieves excellent functions and results as follows:

1. Due to the gold-silicon intermetallic layer has high thermal conductivity, the present invention enhances thermal dissipation capability from the chip to the heatsink;

2. The present invention provides excellent adhesion between the chip and the heatsink and lower CTE mismatch between silicon and adhesion material; and

3. The present invention provides an environment friendly solution by the Pb free process/material.

Although the present invention has been described with reference to specific embodiments, this description is not meant to be construed in a pivoting sense. Various modifications of the disclosed embodiments, as well as alternative embodiments, will be apparent to persons skilled in the art. It is, therefore, contemplated that the appended claims will cover all modifications that fall within the true scope of the present invention.

What is claimed is:

1. A method for a flip chip package, comprising the steps of:
providing a heatsink having a surface plated with a gold film and a bare surface;
providing a chip having a join surface and an active surface with a plurality of contacts;
heating the heatsink over 350° C.;
disposing the join surface of the chip onto the gold film of the heatsink and scrubbing the join surface against the gold film to form a gold-silicon layer by diffusion for connecting the chip to the heatsink;
connecting the active surface of the chip to a substrate by flip chip technology; and
dispensing an underfill into the gap between the chip and the substrate.

2. The method according to claim 1, wherein the step of disposing the join surface onto the gold film comprises providing a clamping apparatus to clamp the chip onto the heatsink.

3. The method according to claim 2, further comprising a step of heating the chip by the clamping apparatus.

4. The method according to claim 3, wherein the chip is heated to between 150° C. and 200° C.

5. The method according to claim 1, further comprising a step of fixing the heatsink by a tooling.

6. The method according to claim 5, wherein the tooling heats the bare surface of the heatsink.

7. The method according to claim 1, wherein the heatsink is heated to over 350° C. and under 450° C.

8. The method according to claim 1, wherein the join surface of the chip and the gold film of the heatsink are scrubbed over 15 seconds.

9. The method according to claim 1, wherein the join surface of the chip and the gold film of the heatsink are scrubbed under 25 seconds.

10. The method according to claim 1, wherein the steps are performed in a nitrogenous ambiance to prevent silicon from oxidization.

11. A structure of a flip chip package, comprising:
a heatsink, having a surface plated with a gold film and a bare surface;
a chip, having a join surface and an active surface with a plurality of contacts;
a gold-silicon intermetallic layer, disposed between the gold film of the heatsink and the join surface of the chip;
a substrate, wherein the active surface of the chip is connected to the substrate by flip chip technology; and
an underfill, dispensed into the gap between the chip and the substrate.

12. The structure according to claim 11, further comprising an encapsulation material surrounding the heatsink and between the heatsink and the substrate.

13. A method for a flip chip package, comprising the steps of:
providing a heatsink having a surface plated with a gold film and a bare surface;
providing a chip having a join surface and an active surface with a plurality of contacts;
eutectic bonding the join surface of the chip to the gold film of the heatsink by gold-silicon diffusion for connecting the chip to the heatsink;
connecting the active surface of the chip to a substrate by flip chip technology; and
dispensing an underfill into the gap between the chip and the substrate.

14. The method according to claim 13, wherein further comprising a step of providing a clamping apparatus to clamp the chip onto the heatsink before the step of eutectic bonding the join surface to the gold film.

15. The method according to claim 14, further comprising a step of heating the chip by the clamping apparatus.

16. The method according to claim 15, wherein the chip is heated to between 150° C. and 200° C.

17. The method according to claim 13, further comprising a step of fixing the heatsink by a tooling.

18. Th method according to claim 17, wherein the tooling heats the bare surface of the heatsink.

19. The method according to claim 17, wherein the heatsink is heated to over 350° C. and under 450° C.

20. The method according to claim 13, wherein the steps are performed in a nitrogenous ambiance to prevent silicon from oxidization.
